(19) United States
(12) Patent Application Publication
(10) Pub. No.: US 2008/0166641 A1
(43) Pub. Date: Jul. 10, 2008

(54) METHOD OF MANUFACTURING COLOR FILTER

(75) Inventors: Sung-woong KIM, Suwon-si (KR); Seok-soon Baek, Suwon-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd., Suwon-si (KR)

(21) Appl. No.: 11/756,051

(22) Filed: May 31, 2007

(30) Foreign Application Priority Data
Jan. 9, 2007 (KR) 2007-2646

(51) Int. Cl. G03F 1/00

(52) U.S. Cl. 430/7

(57) ABSTRACT

A method of forming a color filter including forming a light shielding layer formed of an ink-phobic organic material on a transparent substrate, forming a black matrix that defines pixels by patterning the light shielding layer, treating the surface of the substrate on which the black matrix is formed with hydro fluorine (HF), and filling inks of predetermined color in the pixels.

### CROSS-REFERENCE TO RELATED APPLICATIONS

This application claims the benefit of Korean Patent Application No. 10-2007-0002646, filed on Jan. 9, 2007, in the Korean Intellectual Property Office, the disclosure of which is incorporated herein in its entirety by reference.

### BACKGROUND OF THE INVENTION

1. Field of the Invention

The present general inventive concept relates to a method of manufacturing a color filter, and more particularly, to a method of manufacturing a color filter that can prevent the formation of poor quality pixels.

2. Description of the Related Art

Conventionally, cathode ray tube (CRT) monitors have been generally used to display image information of televisions and computers. However, flat panel displays such as liquid crystal displays (LCDs), plasma display panel (PDPs), organic light emitting diode (OLEDs), light emitting diode (LED) displays, or field emission displays (FEDs) are now being used due to their large screen size. Of the flat panel displays, LCDs, which are mainly used in computer monitors or personal computer notebooks, have drawn much attention due to their low power consumption.

An LCD includes a color filter that forms a desired color image by transmitting white light modulated by a liquid crystal layer. The color filter has a structure in which a plurality of red R, green G, and blue B pixels are arranged in a predetermined pattern on a transparent substrate. The pixels are defined based on a black matrix. To manufacture the color filter, a dyeing method, a pigment dispersion method, a printing method, or an electrode position method has been conventionally used. However, these methods have low process efficiencies and high manufacturing costs since predetermined processes according to each color must be performed repeatedly. Thus, recently, an inkjet method has been proposed since this method is simple, and thus, can reduce manufacturing costs. In the method of manufacturing a color filter using the inkjet method, the color filter is manufactured by ejecting ink droplets of a predetermined color, for example, red R, green G, and blue B color, in the pixels through an inkjet head.

When the color filter is manufactured using the inkjet method, the black matrix is formed of an ink-phobic organic material to prevent ink of different colors from overflowing between adjacent pixels. More specifically, the black matrix is formed by patterning a light shielding layer formed of the ink-phobic organic material after the light shielding layer is formed on a substrate. However, in the process of forming the black matrix, the ink-phobic organic material can remain on a surface of the substrate in the pixels. If the ink-phobic organic material remains on the surface of the substrate in the pixels, ink can be partly filled in the pixels. As a result, poor quality pixels can be formed.

### SUMMARY OF THE INVENTION

The present general inventive concept provides a method of manufacturing a color filter that can prevent the formation of poor quality pixels.

Additional aspects and utilities of the present general inventive concept will be set forth in part in the description which follows and, in part, will be obvious from the description, or may be learned by practice of the general inventive concept.

The foregoing and/or other aspects and utilities of the present general inventive concept are achieved by providing a method of manufacturing a color filter, including forming a light shielding layer formed of an ink-phobic organic material on a transparent substrate, forming a black matrix that defines pixels by patterning the light shielding layer, treating the surface of the substrate on which the black matrix is formed with hydro fluorine (HF), and filling inks of predetermined color in the pixels.

The substrate may be formed of glass.

The light shielding layer may be formed by soft baking the ink-phobic organic material after coating the ink-phobic organic material on the substrate.

If the light shielding layer is formed of a photosensitive material, the forming of the black matrix may include exposing and developing the light shielding layer and hard baking the developed light shielding layer.

If the light shielding layer is formed of a non-photosensitive material, the forming of the black matrix may include exposing and developing a photoresist after coating the photoresist on the upper surface of the light shielding layer, etching the light shielding layer until the substrate is exposed using the developed photoresist as an etch mask, and hard baking the etched light shielding layer.

The treating of the surface of the substrate with HF may include etching the surface of the substrate by soaking the substrate on which the black matrix is formed in a HF solution, and washing and drying the substrate. In the process of etching the surface of the substrate with HF, the ink-phobic organic materials remaining on the surface of the substrate in the pixels may be removed.

The filling of the inks in the pixels may be performed by an inkjet method.

The foregoing and/or other aspects and utilities of the present general inventive concept are achieved by providing a method of manufacturing a color filter, including forming a light shielding layer including an ink-phobic organic material on a transparent substrate, forming a pattern from the light shielding layer, treating the surface of the substrate on which the pattern is formed, and filling inks of predetermined color in the pattern.

The forming of the pattern can define pixels in which the inks of the predetermined colors are filled.

The treating of the surface of the substrate on which the pattern is formed can be performed by coating the surface with hydro fluorine (HF) by one of spin coating, die coating, or dip coating.

### BRIEF DESCRIPTION OF THE DRAWINGS

These and/or other aspects and utilities of the present general inventive concept will become apparent and more readily appreciated from the following description of the embodiments, taken in conjunction with the accompanying drawings of which:

FIGS. 1 through 5 are cross-sectional views illustrating a method of manufacturing a color filter according to an embodiment of the present general inventive concept; and

FIGS. 6A and 6B are photo images showing spreadability of ink droplets on a surface of a substrate in pixels before and after treating the surface of the substrate with hydrogen fluoride (HF).

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

FIGS. 1 through 5 are cross-sectional views illustrating a method of manufacturing a color filter according to an embodiment of the present general inventive concept.

Referring to FIG. 1, a light shielding layer 110 is formed on a substrate 100. The substrate 100 can be an glass substrate, but the present general inventive concept is not limited thereto. That is, the substrate 100 can be any substrate that can be etched by using hydrogen fluoride (HF), which will be described later. The light shielding layer 110 can be formed of an ink-phobic organic material. The light shielding layer 110 can be formed by softly baking an ink-phobic organic material after the ink-phobic organic material is coated to a predetermined thickness on the substrate 100. The ink-phobic organic material can be coated on the substrate 100 using a coating method such as spin coating, die coating, or dip coating. The soft baking process can be performed at a temperature of 80 to 120° C. for 30 seconds to 2 minutes, but the present general inventive concept is not limited thereto.

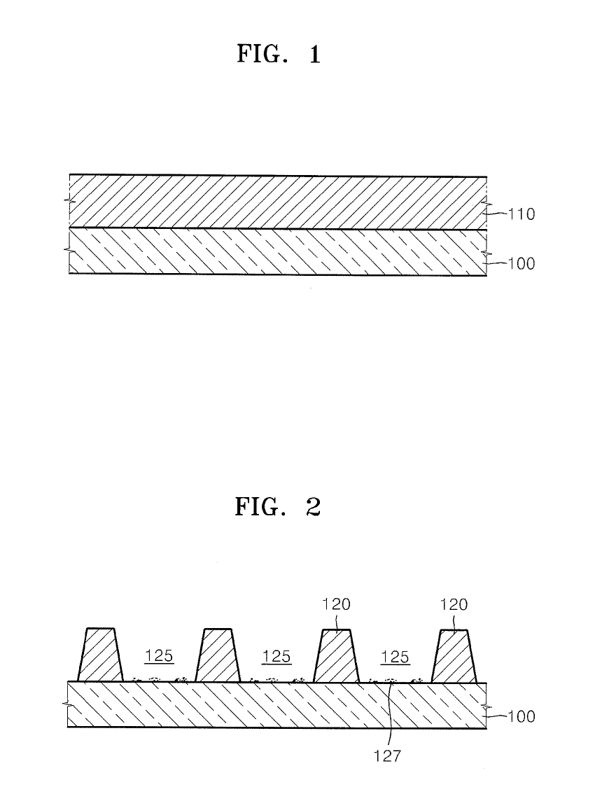

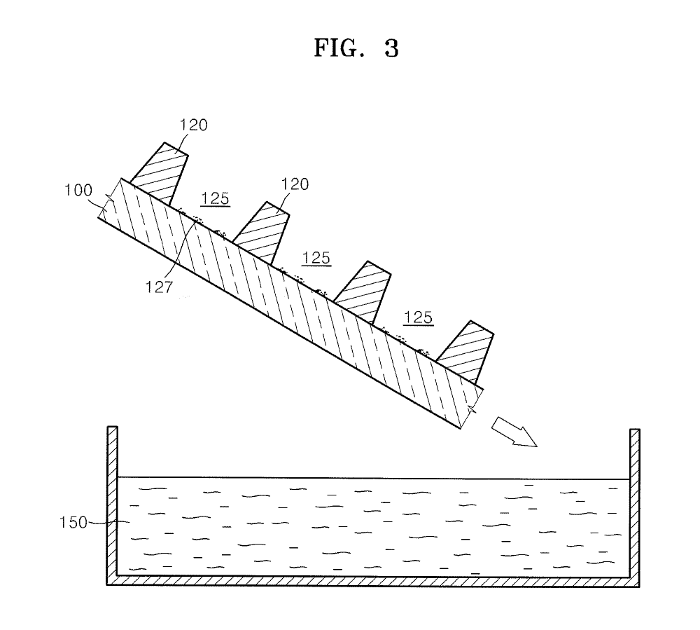

Referring to FIG. 2, a black matrix 120 is formed by patterning the light shielding layer 110. Pixels 125 are defined on the substrate 100 by the black matrix 120. More specifically, if the black matrix 120 is formed of a photosensitive material, the black matrix 120 can be formed by hard baking the light shielding layer 110 after the light shielding layer 110 is exposed and developed using a photmask (not illustrated) on which a predetermined pattern is formed. The hard baking process can be performed at a temperature of 200 to 230° C. for 20 to 40 minutes, but the present general inventive concept is not limited thereto. If the light shielding layer 110 is formed of a non-photosensitive material, a photoresist (not illustrated) is coated on the upper surface of the light shielding layer 110, and the coated photresist is exposed and developed. Next, the light shielding layer 110 is etched until the substrate 100 is exposed using the developed photresist as an etch mask. If the etched light shielding layer 110 is hard baked, the black matrix 120 is formed. The black matrix 120 formed in this way has a height of approximately 1.5 μm and a width of approximately 30 μm. In the process of forming the black matrix 120, for example, the developing process or the baking process, the ink-phobic organic materials 127 that constitutes the black matrix 120 can remain on the surface of the substrate 100 in the pixels 125.

Referring to FIG. 3, the substrate 100 on which the black matrix 120 is formed is soaked in an HF solution 150. At this point, the surface of the substrate 100 is etched by HF. For example, if the substrate 100 is formed of glass, the etching reaction of the substrate 100 by HF is as follows.

SiO₂+6HF→H₂SiF₆+2H₂O <Reaction 1>

According to the above reaction, the surface of the substrate 100 is etched by HF, and also, in this process, the ink-phobic organic materials 127 remaining on the surface of the substrate 100 in the pixels 125 are removed. Since the black matrix 120 is non-reactive to the HF solution 150, the ink-phobic property of the black matrix 120 is maintained.

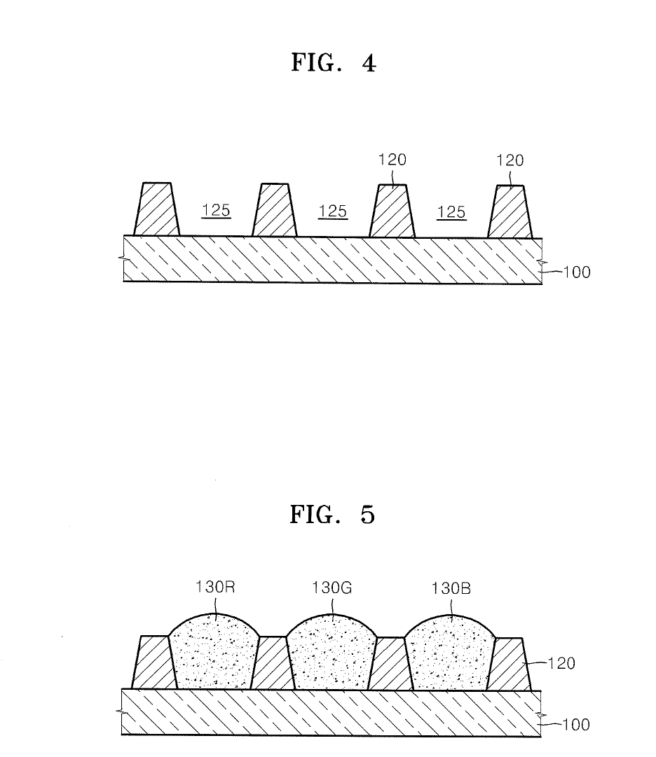

When the substrate 100 treated with HF is washed and dried, as depicted in FIG. 4, the ink-phobic organic material 127 that can remain in the pixels 125 through the process of forming the black matrix 120 can be removed from the surface of the substrate 100.

Referring to FIG. 5, the manufacture of a color filter is completed when predetermined color inks, for example, red ink 130R, green ink 130G, and blue ink 130B, are filled in the pixels 125 defined by the black matrix 120. The filling of inks 130R, 130G, and 130B in the pixels 125 can be performed by an inkjet method. In this case, if predetermined colors of ink droplets are ejected into the pixels 125 through an inkjet head (not illustrated), the inks 130R, 130G, and 130B are filled in the pixels 125.

As described above, after the black matrix 120 is formed, if the substrate 100 is treated with HF, the ink-phobic organic materials 127 are removed from the surface of the substrate 100 in the pixels 125, and thus, the spreadability of the inks 130R, 130G, and 130B on the surface of the substrate 100 in the pixels 125 can be increased. Thus, the inks 130R, 130G, and 130B can be uniformly filled in the entire pixels 125. After the treatment with HF, the ink-phobic property of the black matrix 120 is unchanged. Therefore, the overflow of the inks 130R, 130G, and 130B between pixels 125 can be prevented.

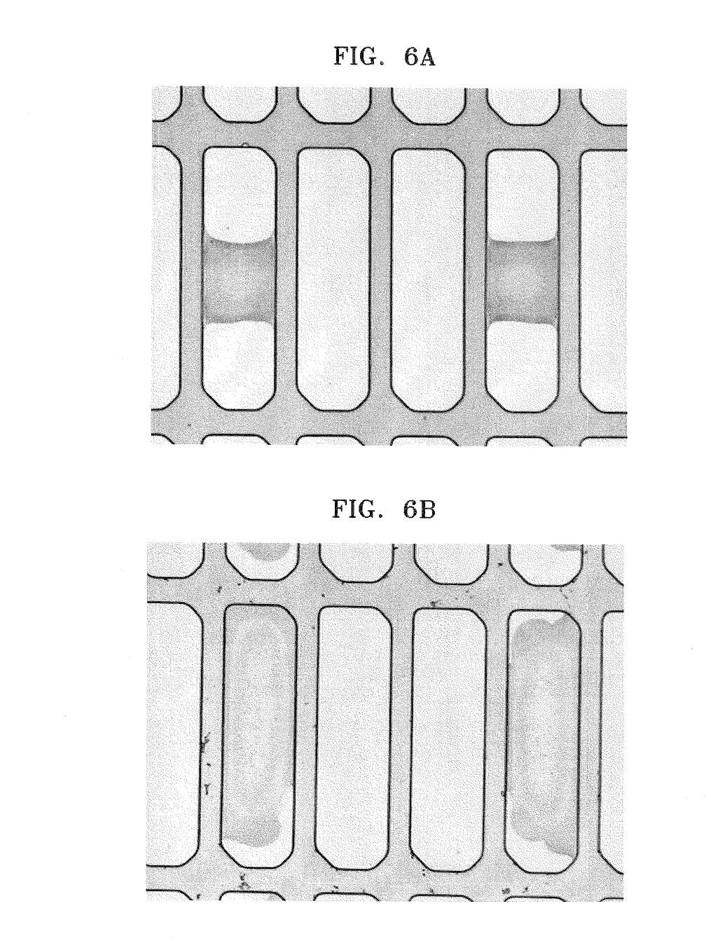

FIGS. 6A and 6B are photo images showing spreadability of ink droplets on a surface of a substrate in pixels before and after treating the surface of the substrate with hydrogen fluoride (HF). Referring to FIG. 6A and 6B, before the surface of the substrate is treated with HF, ink droplets are spread dispersed on a portion of the surface of the substrate in each of the pixels. However, after the surface of the substrate is treated with HF, the ink droplets are uniformly spread dispersed on the surface of the substrate in each of the pixels.

Contact angles on a surface of the black matrix 120 before and after treating with HF are measured. HF solution in which NH₄F and HF are mixed 6:1 is used, and a solvent used for measuring the contact angles is dipropylene glycol methyl ether acetate (DPMA). The result shows that the contact angle of the black matrix 120 before treating with HF is 24°, and when the treating times are 30 seconds, 1 minute, 3 minutes, and 5 minutes, the contact angles respectively are 24.5°, 24.5°, 24.7°, and 24.5°. From the experimental results it can be said that the black matrix 120 has almost a constant contact angle regardless of the treating or non-treating the surface of the substrate with HF.

As described above, according to the present general inventive concept, ink-phobic organic materials remaining on the surface of a substrate in pixels can be removed by treating with HF after the black matrix is formed. Thus, ink can be uniformly spread in the entire pixels, thereby preventing the formation of poor quality pixels. Also, since the ink-phobic property of the black matrix is maintained after treating with HF, the overflow of ink of different colors between the pixels can be prevented.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A method of manufacturing a color filter, comprising:
forming a light shielding layer formed of an ink-phobic organic material on a transparent substrate;
forming a black matrix that defines pixels by patterning the light shielding layer;
treating the surface of the substrate on which the black matrix is formed with hydro fluorine (HF); and
filling inks of predetermined color in the pixels.

2. The method of claim 1, wherein the substrate is formed of glass.

3. The method of claim 1, wherein the light shielding layer is formed by soft baking the ink-phobic organic material after coating the ink-phobic organic material on the substrate.

4. The method of claim 1, wherein, if the light shielding layer is formed of a photosensitive material, the forming of the black matrix comprises:
exposing and developing the light shielding layer; and
hard baking the developed light shielding layer.

5. The method of claim 1, wherein, if the light shielding layer is formed of a non-photosensitive material, the forming of the black matrix comprises:
exposing and developing a photoresist after coating the photoresist on the upper surface of the light shielding layer;
etching the light shielding layer until the substrate is exposed using the developed photoresist as an etch mask; and
hard baking the etched light shielding layer.

6. The method of claim 1, wherein the treating of the surface of the substrate with HF comprises:
etching the surface of the substrate by soaking the substrate on which the black matrix is formed in a HF solution; and
washing and drying the substrate.

7. The method of claim 6, wherein, in the etching of the surface of the substrate with HF, the ink-phobic organic materials remaining on the surface of the substrate in the pixels are removed.

8. The method of claim 1, wherein the filling of the inks in the pixels is performed by an inkjet method.

9. A method of manufacturing a color filter, comprising:
forming a light shielding layer including an ink-phobic organic material on a transparent substrate;
forming a pattern from the light shielding layer;
treating the surface of the substrate on which the pattern is formed; and
filling inks of predetermined color in the pattern.

10. The method of claim 9, wherein the forming of the pattern defines pixels in which the inks of the predetermined colors are filled.

11. The method of claim 9, wherein the treating of the surface of the substrate on which the pattern is formed is performed by coating the surface with hydro fluorine (HF) by one of spin coating, die coating, or dip coating.
